(19) United States
(12) Patent Application Publication
(10) Pub. No.: US 2020/0315025 A1
(43) Pub. Date: Oct. 1, 2020

(54) Printed Circuits on and within Porous, Flexible Thin Films

(71) Applicant: The Government of the United States of America, as represented by the Secretary of the Navy, Arlington, VA (US)

(72) Inventors: Jonathan D. Yuen, Washington, DC (US); David A. Stenger, Annapolis, MD (US); Daniel Zabetakis, Brandywine, MD (US); Scott Walper, Springfield, VA (US); Banahalli R. Ratna, Alexandria, VA (US)

(21) Appl. No.: 16/828,387

(22) Filed: Mar. 24, 2020

Related U.S. Application Data
(60) Provisional application No. 62/823,056, filed on Mar. 25, 2019.

(51) Int. Cl. H05K 3/18; H05K 3/12; H05K 3/34; H05K 1/09; C23C 18/18

(52) U.S. Cl. CPC H05K 3/181; H05K 3/125; C23C 18/1879; H05K 1/092; H05K 3/341

(57) ABSTRACT

Patterns of homogenous, electroless-plated metals within and on one or both sides of a porous substrate (such as nanocellulose sheets) enable the formation of an matrix of metal within pores of the substrate that can connect patterns on both sides of the substrate. These can serve as circuits with applications in, for example, wearable electronics.

### CROSS-REFERENCE TO RELATED APPLICATIONS

This Application claims the benefit of U.S. Provisional Patent Application No. 62/823,056 filed Mar. 25, 2019, the entirety of which is incorporated herein by reference.

This Application is related to both U.S. Patent Application Publication No. 2016/0198984 and to U.S. Pat. No. 9,720,318 issued on Aug. 1, 2017.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; techtran@nrl.navy.mil, referencing NC 108,542.

### BACKGROUND

Wearable devices, such as wear-and-forget health monitoring systems, should ideally be imperceptible. To this end, they are preferably very thin, conformal to the contours of the skin, self-adhering, ultra-lightweight, and translucent. While ultra-thin polymer sheets do exist, printing with typically hydrophilic inks on hydrophobic polymeric substrates is challenging. Additionally, issues with breathability and biocompatibility hinder their utility for health related applications.

In response to these issues, a process was developed to create microbial nanocellulose sheets thinner than 20 μm, resulting in a new material class. See U.S. Pat. No. 9,720,318. These ultrathin sheets present opportunities for various applications, especially for flexible electronics. Microbial nanocellulose is highly chemical and solvent resistant, mechanically strong, water permeable, and biocompatible. Nanocellulose sheets are grown in-situ from microbial broth as millimeter-thick gel layers, and can be of any arbitrary size or shape as determined by the growth vat. The gel layers can be laminated onto a wide range of substrates, and upon drying, shrink laterally into microns-thick sheets. These sheets can be easily delaminated from the substrate simply by moistening the film, resulting in a freestanding microns-thick film. Moistening the film does not return it to the gel state; rather, it retains its sheet-like characteristics. The porosity of such nanocellulose sheets makes them amenable to the wicking effect, allowing the absorption of most liquids into the nanocellulose matrix. Other types of flexible, free-standing substrates below 20 μm that contain a porous network are extremely rare and very difficult to manufacture in bulk. Even in the rarely available cases, the pores in the so-called porous films below 20 μm are actually through-holes that cut directly through both sides of the film, rendering the films more like sieves.

A need exists for technologies relating to wearable electronics.

### BRIEF SUMMARY

Aspects described herein relate to the application of current state-of-the-art printed circuit board (PCB) technology for the construction of flexible electronics on porous, ultrathin substrates that are merely microns-thick.

In one embodiment, method of forming a circuit includes printing a pattern of catalytic ink onto a porous nanocellulose sheet, wherein the pattern represents a desired circuit; and then performing electroless plating to convert the ink to a conductive metal matrix existing within pores of the nanocellulose and having a form of the desired circuit.

In a further embodiment, a method of forming a circuit includes printing patterns of catalytic ink onto each of two opposing faces of a porous nanocellulose sheet having a thickness of no greater than 20 μm, wherein the patterns represent a desired circuit comprising at least one via interconnecting the opposing faces; and then performing electroless plating to convert the ink to a conductive metal matrix existing within pores of the nanocellulose and having a form of the desired circuit.

### BRIEF DESCRIPTION OF THE DRAWINGS

FIGS. 1A-1D provide a schematic depictions of various exemplary structures that can be formed, with FIG. 1A showing a single plated metallic layer formed on the surface of the porous sheet. The layer partially penetrates the porous substrate as the catalyst ink has only partially penetrated the substrate during printing. FIG. 1B describes a plated structure with the ink fully penetrating the substrate to the opposite side, resulting in a layer of metal on each side of the sheet, and with an interconnecting metal-pore-substrate matrix joining the two surface layers. FIG. 1C shows two structures resulting from ink printed separately on both sides of the sheet in which ink has not completely suffused the substrate, resulting in two partially penetrated metal layers that do not come in contact with each other. FIG. 1D describes the structures formed when ink patterns printed on both sides of the substrate come in contact with each other at certain sections of the substrate. Vias between the metal wiring on each side of the sheet are formed where the original ink patterns overlap.

FIG. 2 is a flowchart describing an exemplary process to produce electroless plated metal layers on both sides of nanocellulose sheets.

FIGS. 3A-3D show the process of printing patterns of catalyst ink on both sides of a nanocellulose sheet: In FIG. 3A, a blank nanocellulose sheet on a glass wafer is shown loaded onto an inkjet printer; FIG. 3B shows the nanocellulose sheet with a pattern of palladium catalyst ink printed on one side; in FIG. 3C the nanocellulose sheet is seen with another pattern printed on the other side of the sheet as indicated by the darker, overlapping regions; and FIG. 3D the nanocellulose sheet is shown secured on a substrate designed as a sample holder for plating.

FIGS. 4A and 4B show the electroplated nanocellulose sheet from FIG. 3D with surface-mounted electronic components soldered on at the front and back (FIGS. 4A and 4B, respectively).

FIGS. 5A-5D show the nanocellulose sheet after the electronic components have been soldered on, and its operation as a pulse oximeter: FIG. 5A the front of the sheet with secondary components and wiring; FIG. 5B the back of the sheet consisting the LED and photodiode; FIG. 5C the LED illuminated when connected to power; and FIG. 5D a pulse measurement taken with the nanocellulose pulse oximeter.

### DETAILED DESCRIPTION

### Definitions

Before describing the present invention in detail, it is to be understood that the terminology used in the specification is for the purpose of describing particular embodiments, and is not necessarily intended to be limiting. Although many methods, structures and materials similar, modified, or equivalent to those described herein can be used in the practice of the present invention without undue experimentation, the preferred methods, structures and materials are described herein. In describing and claiming the present invention, the following terminology will be used in accordance with the definitions set out below.

As used herein, the singular forms “a”, “an,” and “the” do not preclude plural referents, unless the content clearly dictates otherwise.

As used herein, the term “and/or” includes any and all combinations of one or more of the associated listed items.

As used herein, the term “about” when used in conjunction with a stated numerical value or range denotes somewhat more or somewhat less than the stated value or range, to within a range of ±10% of that stated.

As used herein, the term “electroless” refers to a plating method conducted in solution and occurring without the use of external electrical power.

Overview

Described herein is a technique for the printing of metallic components on ultrathin microbial nanocellulose sheets (typically 20 μm thick or less) to form continuous metallic films. In particular, this involves the formation of patterns of homogenous, electroless-plated metals within and on one or both sides of a porous substrate, thereby enabling the formation of an matrix of metal within pores of the substrate that can connect patterns on both sides of the substrate.

Such a printed pattern, also termed a wiring matrix, allows for the soldering of a thin-film electronic device, or series of electronic devices, thereby forming a nanocellulose printed circuit.

Nanocellulose is a crystalline or semi-crystalline phase of cellulose in which at least one dimension is on the nanoscale. Microbial nanocellulose is nanocellulose grown as a product of certain bacteria, such as Acetobacter xylinum, through ingestion of glucose (fermentation). The fabrication of the nanocellulose printed circuit board involves three separate processes: (1) the printing of ink, for example an ink comprising palladium (Pd) catalyst; (2) the electroless plating of the metal(s); and (3) the soldering of electronic surface-mounted components.

One can distinguish between printing on polymer versus porous nanocellulose materials. Currently, a popular approach entails the use of silver nanoparticle inks or silver precursor inks to deposit patterns of silver. However, there are limitations with polymer substrates since most polymers cannot withstand the high temperature anneal required to achieve high conductivities, and that this printing process is currently limited to silver. Electroless metallization is a low temperature solution-based process that allows the plating of a variety of metals, such as gold, silver, nickel and copper. Spontaneous deposition of metallic films on a surface occurs under the initiation of a catalytic palladium nanoparticle ink printed on the surface. It is an underexplored process due to the difficulty of printing the aqueous, acidic palladium nanoparticle catalyst ink onto hydrophobic plastic substrates. Due to such challenges, the general manufacturing practice is to adhere thin metallic sheets to the plastic substrates with adhesives instead.

Printing circuits on porous substrates remains, by and large, at the R&D stage. While there has been work done on selectively filling areas of the porous substrate with conductive material to create vias to electrically connect between components on both sides of the substrate, the metal films on the surface of the porous substrate is of a different material than the conductive filler in the porous matrix. In other words, two separate processes are required: infusing selected areas of the porous substrate with conductive material of poorer conductivity, and then contacting the areas with another more conductive material. In general, the porous substrate is filled with a conductive ink directly printed into the substrate, but the contacts of the via are attached in a separate process. The process typically results in a poor electrical contact, as compared to a homogenous metallic contact.

Various processing capabilities have been developed for such fabrication of electronics on nanocellulose sheets. The sheets are amenable to microfabrication processes, of which optical lithography, vacuum evaporation and dry etching have been demonstrated. With their porosity, nanocellulose sheets easily wick inks, and are therefore also amenable to solution-based processing. The ability exists to print both insulating and semiconducting materials on nanocellulose sheets, including an insulating polymer, SU8, and a semiconducting polymer, PEDOT:PSS.

Three primary aspects distinguish the techniques described herein from previous work relating to printing on porous substrates. First, the hydrophilicity and the porosity of the nanocellulose sheets allow ample ink infiltration and adhesion to the nanocellulose matrix which in turn enable effective plating, resulting in the formation of smooth and continuous metallic films. Practically without exception, any location within or on the nanocellulose sheet which is covered with the catalyst ink becomes coated with metallic film. Second, due to the extreme thinness of the porous substrates and in-built smooth, continuous metallic films, electronic infrastructure, either a thin-film electronic device or series of electronic devices on both sides of the substrate can be readily linked via an intervening matrix of the same metal. Without the need to create through-holes or inject lower-conductivity material into the porous matrix, this technology in turn helps minimize the thickness of our electronic device and remove the need for additional fabrication steps. Third, this is believed to be the first employment of electroless metallization to form a metallic infrastructure on a porous flexible surface.

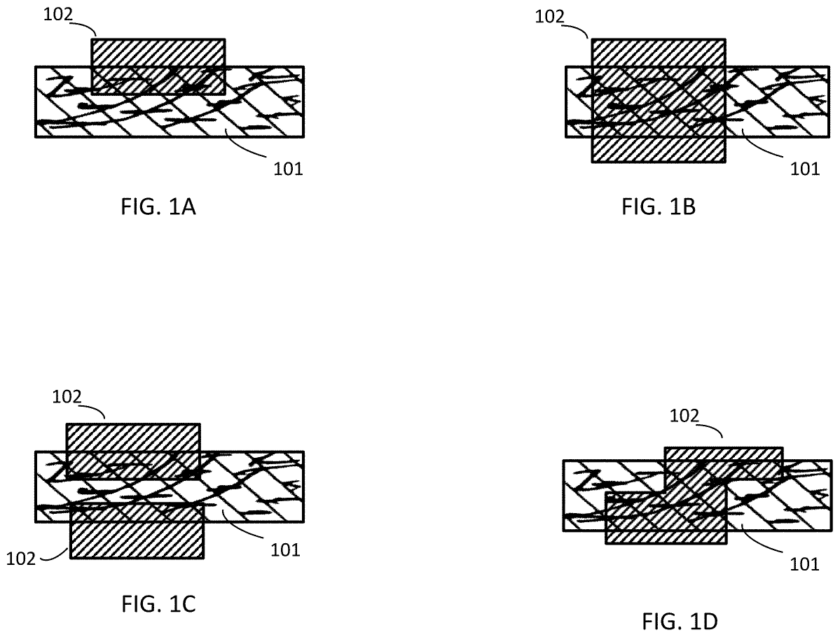

Different configurations of metallic film structures can be electroless-plated on one or both surfaces, and within a flexible, porous substrate. FIGS. 1A-1D provide cross-sectional schematic views of various metallic structures that can be formed. FIG. 1A shows a single plated metallic layer 102 formed on the surface of a porous sheet of nanocellulose 101. The layer partially penetrates the porous substrate as the catalyst ink has only partially penetrated the substrate during printing. In this and the other figures, the area of the illustration where the two materials 101 and 102 are overlapped indicates that a matrix of metal exists within pores of the substrate. FIG. 1B depicts a plated structure 102 with the ink fully penetrating the substrate 101 to the opposite side, resulting in a layer of metal on each side of the sheet, and with an interconnecting metal-pore-substrate matrix joining the two surface layers, able to act as a via. FIG. 1C shows two structures resulting from ink printed separately on both sides of the sheet in which ink has not completely suffused the substrate 101, resulting in two partially penetrated metal layers 102 that do not come in contact with each other. FIG. 1D illustrates the structure formed when ink patterns printed on both sides of the 101 substrate come in contact with each other at certain sections of the substrate. Vias between the metal wiring on each side of the sheet 102 are formed where the original ink patterns overlap.

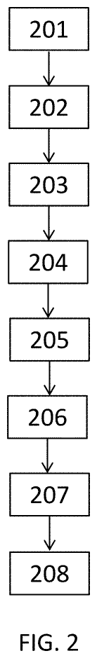

In FIG. 2, a flowchart depicts steps in an exemplary process for making structures as described herein. In step 201, catalyst ink is printed onto a top surface of a nanocellulose sheet using an inkjet process. In step 202, the nanocellulose sheet is wetted and detached from a substrate (such as a glass wafer). Optionally, the sheet can then be inverted and reattached to the substrate in step 203, allowing for printing on a bottom surface in step 204. In step 205, the printed sheet is wetted, detached, reinverted if necessary, and attached to a transparency sheet. Optionally, the printed sheet can be secured with tape in step 206. Then it is immersed in a plating bath (step 207) before being cleaned and dried (step 207).

### Examples

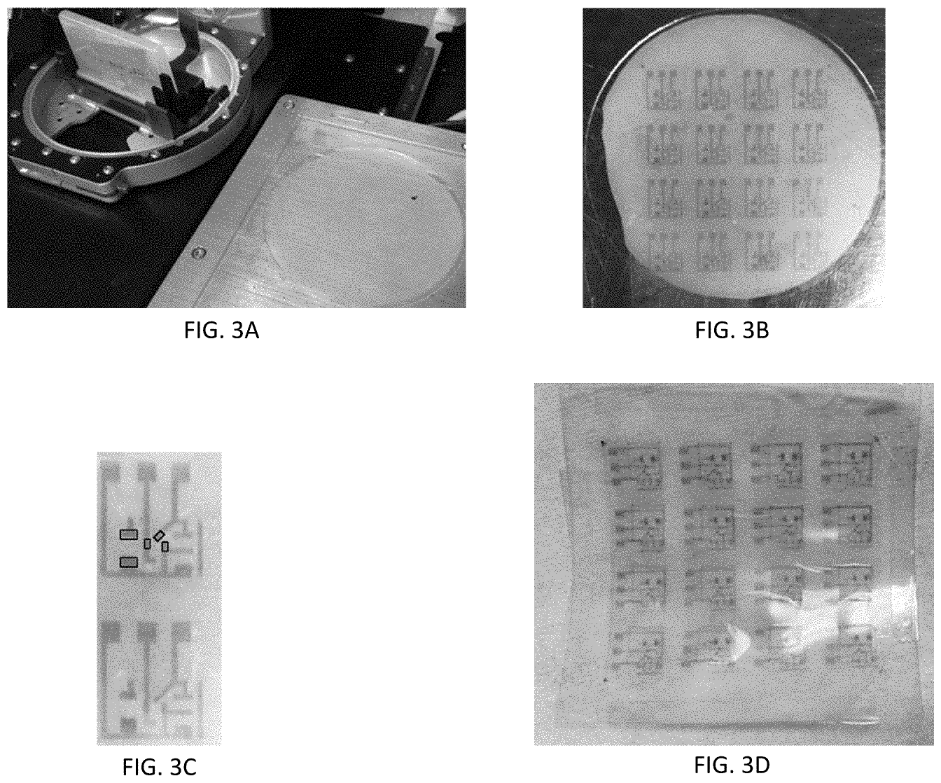

Inkjet printing was used to create patterns of palladium catalyst on the nanocellulose using a FujiFilm Dimatix DMP-2831 Materials Printer on a nanocellulose sheet laminated on a glass wafer, as shown in FIG. 3A. Cataposit 44 (Rohm & Haas), used as received, was diluted 1:6 with 11% hydrochloric acid and filtered into a DMC-11610 cartridge (10 pL drop-size) with a 0.2 μm Nalgene PTFE syringe filter. During printing, the platen temperature was set at 37° C. and the cartridge temperature was left at room temperature. Printing was performed at a resolution of 1270 DPI, with the jetting voltage range between 15-35 V and only 4 of the 16 jets used. FIG. 3B shows a catalyst ink-printed nanocellulose sheet on a glass wafer, which represents the top part of a wiring diagram for a pulse oximeter.

To form two interconnected patterns, one on each side of the nanocellulose, the wafer was immersed into a water bath, and the nanocellulose sheet was peeled off, flipped and relaminated on the glass wafer such that the unprinted side of the nanocellulose sheet faced upward. Inkjet printing of the Pd catalyst was performed under the same conditions as above with a section of the pattern on top overlapping the pattern underneath. In this example, these are represented as small contact pads for an LED and a photodiode directly above the pattern below, as shown in FIG. 3C. After the printing process was completed, the substrate was immersed in DI water to remove the acid in the ink, and the printed nanocellulose sheet was peeled off the glass wafer it was mounted on. The peeled sheet was remounted while still in DI water onto a transparency sheet, then removed from the DI bath and air-dried. Upon drying, double-sided tape was attached to the edges of the transparency to secure the nanocellulose sheet, as shown in FIG. 3D.

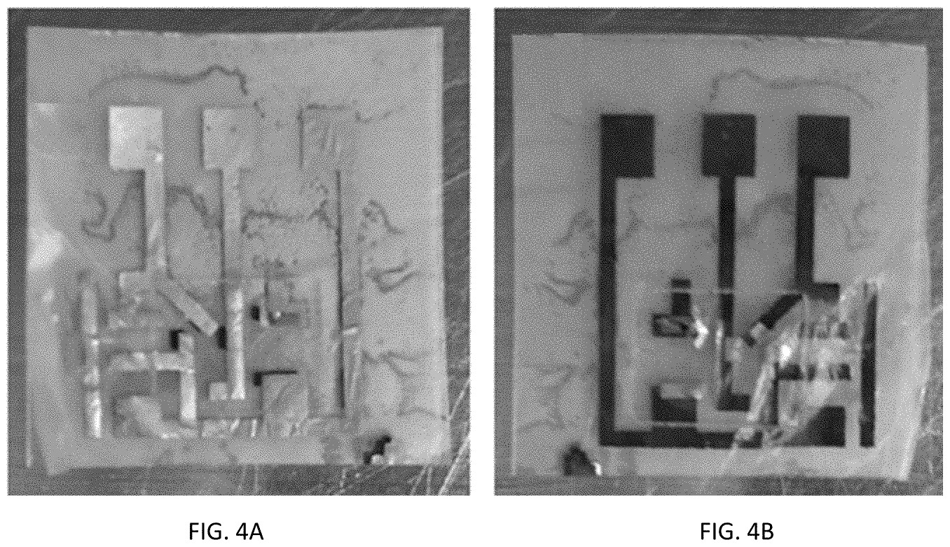

For the next process, electroless plating was employed to create metallic wiring patterns on the nanocellulose sheet. Electroless plating is defined as a low temperature, non-galvanic, redox precipitation (below 100° C.) where spontaneous deposition of metallic films on a surface occurs under the initiation of a catalytic palladium nanoparticle catalyst adhered on the surface. For this example, three layer of different metals, copper, nickel and gold were plated onto the catalyst patterns by immersing the mounted transparency sheet into specific chemical baths. Plating of copper was carried out using Cuposit 328 electroless copper plating solution at 55-60° C.; plating of nickel was carried using Duraposit SMT88 electroless nickel plating solution at 88° C.; and plating of gold with Aurolectroless 520 gold plating solution at 88° C. Upon the completion of each plating step, the sample was soaked in water (three changes) to remove the residual electroless bath. After the successive plating steps, the sample was left overnight to air-dry. The result of the plating process on the same substrate illustrated in FIG. 3B is shown in FIGS. 4A and 4B, with the main wiring pattern shown in FIG. 4A, and the LED and photodiode pads shown in FIG. 4B.

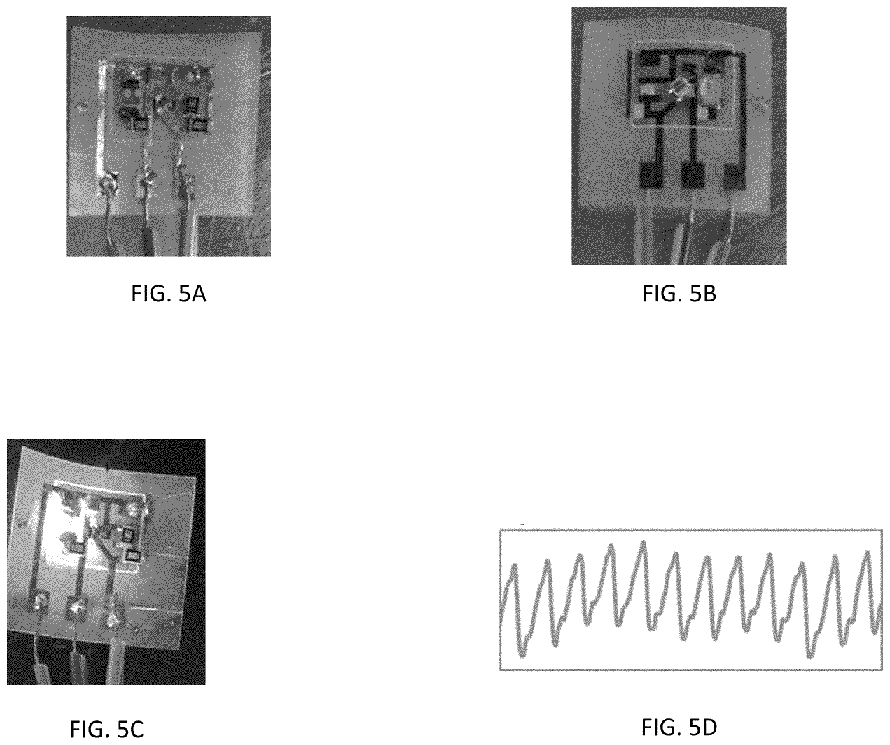

Finally, electronic surface-mounted components were soldered onto the metal wiring patterns on the porous substrate, resulting in completed electronic devices. One example was a pulse oximeter operable to measure human heart-rate. Soldering was performed using standard procedures, with the exception that the solder used was a low melting point alloy, Field's Metal. FIGS. 5A and 5B show the plated nanocellulose sheet depicted in FIGS. 4A and 4B, now with electronic surface-mounted components soldered onto it. FIG. 5A shows the soldered main wiring pattern, consisting the secondary electronics not directly involved in pulse oximetry measurement, and the wires that connect to the power source. FIG. 5B shows the opposite side of the substrate, with the soldered-on LED and the photodiode that perform the pulse measurement. FIGS. 5C and 5D show the device in operation, with FIG. 5C showing the LED lit when a voltage is applied from the wires of the electrode, indicating that the wiring on both sides of the sheet are in contact with each other; and FIG. 5D showing pulse measurement data taken using the monitor.

### Further Embodiments

It is expected that this technique would be operable on other types of insulating porous substrates, both organic and inorganic. Examples include polyurethane, alumina, titania, silica, carbon, zeolite, Styrofoam, polycarbonate, polyamide, Teflon, polyisoprene, polysulfone, cellulosic materials, and polyethylene. Moreover, several sources exist for nanocellulose: bacterial, tunicate, plant, other biomass, etc.

A variety of metals and semimetals might be used for plating, such as tin, palladium, platinum, silver, iron, cobalt, as well as alloys containing one of more of the elements stated.

Alternative printing methods can be considered, and are not limited to, screen-printing, lithography, gravure, roll-to-roll, spray-printing, batik, laser, flexography, thermal-printing, stamping and intaglio.

Alternative methods for attaching electronics can be considered, such as replacing solder with conductive epoxy, ball bonding, and adhesives.

Advantages

Exploiting the porosity and thinness of a free-standing, ultrathin, porous substrate with the formation of metallic wiring patterns, particularly in forming interconnects (or vias) between wiring patterns on both sides of the substrate. As mentioned previously, until now, this has been typically achieved by the infusion of a material of lower conductivity, such as carbon or silver paste, into specific areas of a porous substrate, followed by capping the surfaces of the infused matrix with a material of a higher conductivity, such as copper foil. This process requires at least 2 separate processing steps, and the high viscosity of the paste precludes substrates with fine pores as penetration is impossible. As pore size increases, the thin substrate becomes less mechanically stable. The described process of electroless plating within the pores of the substrate not only can be completed in a single step, it is suitable for very thin porous substrates with fine pores, and can form vias consisting of material identical to that of the metal films formed on the surfaces, and therefore of the same conductivity. As far as we are aware, this novel structure has not been reported in patent literature and will serve to extend the utility of nanocellulose sheets to house surface-mounted electronic components

Concluding Remarks

All documents mentioned herein are hereby incorporated by reference for the purpose of disclosing and describing the particular materials and methodologies for which the document was cited.

Although the present invention has been described in connection with preferred embodiments thereof, it will be appreciated by those skilled in the art that additions, deletions, modifications, and substitutions not specifically described may be made without departing from the spirit and scope of the invention. Terminology used herein should not be construed as being “means-plus-function” language unless the term “means” is expressly used in association therewith.

What is claimed is:

1. A method of forming a circuit, comprising:
printing a pattern of catalytic ink onto a porous nanocellulose sheet, wherein the pattern represents a desired circuit; and then
performing electroless plating to convert the ink to a conductive metal matrix existing within pores of the nanocellulose and having a form of the desired circuit.

2. The method of claim 1, wherein the printing is inkjet printing.

3. The method of claim 1, further comprising a step of bonding one or more electrical components to the conductive metal matrix via soldering.

4. The method of claim 1, wherein the nanocellulose sheet has a thickness of no greater than 20 μm.

5. The method of claim 1, wherein each of two opposing faces of the sheet receive printing and plating so that circuits are formed on each of the faces.

6. The method of claim 5, wherein conductive vias are formed between the two opposing faces.

7. A method of forming a circuit, comprising:
printing patterns of catalytic ink onto each of two opposing faces of a porous nanocellulose sheet having a thickness of no greater than 20 μm, wherein the patterns represent a desired circuit comprising at least one via interconnecting the opposing faces; and
then performing electroless plating to convert the ink to a conductive metal matrix existing within pores of the nanocellulose and having a form of the desired circuit.

8. The method of claim 7, further comprising a step of bonding one or more electrical components to the conductive metal matrix via soldering.
